(19) United States
(12) Patent Application Publication
(10) Pub. No.: US 2005/0287394 A1
(43) Pub. Date: Dec. 29, 2005

(54) Iridium compound and organic electroluminescent device using the same

(76) Inventors: Seung-Gak Yang, Suwon-si (KR); Seok-Jong Lee, Suwon-si (KR); Hee-Yeon Kim, Suwon-si (KR); Seok-Hwan Hwang, Suwon-si (KR); Young-Kook Kim, Suwon-si (KR); Dong-Hyun Jung, Suwon-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/157,422

(22) Filed: Jun. 21, 2005

(30) Foreign Application Priority Data
Jun. 23, 2004 (KR) 10-2004-0046957

(51) Int. Cl. B32B 19/00

(52) U.S. Cl. 428/690

(57) ABSTRACT

An iridium compound is provided which is used as a light-emitting layer material of an organic EL device. An organic EL device using the iridium compound is high in device characteristics, including emission efficiency, brightness, color purity, and lifetime characteristics is also provided.

### BACKGROUND OF THE INVENTION

This application claims the priority of Korean Patent Application No. 10-2004-0046957, filed on Jun. 23, 2004, in the Korean Intellectual Property Office, the disclosure of which is incorporated herein in its entirety by reference.

### FIELD OF THE INVENTION

The present invention relates to an iridium compound and an organic electroluminescent device using the same. More particularly, the present invention relates to an iridium compound used as a novel blue phosphorescent material and an organic electroluminescent device using the iridium compound as an organic layer material.

### DESCRIPTION OF THE RELATED ART

Common organic electroluminescent (“EL”) devices have a sequentially stacked structure of an anode, a hole transport layer, a light-emitting layer, an electron transport layer, and a cathode, on an upper surface of a substrate. The hole transport layer, the light-emitting layer, and the electron transport layer are organic layers made of an organic compound.

The organic EL device with the above-described structural feature is driven as follows.

When a voltage is applied to the anode and the cathode, holes from the anode are transferred to the light-emitting layer via the hole transport layer. On the other hand, electrons from the cathode are transferred to the light-emitting layer via the electron transport layer. These carriers recombine at the light-emitting layer to generate excitons. When the excitons are changed from an excited state to a ground state, fluorescent molecules of the light-emitting layer emit light, thus creating an image. Here, light emission by transition from a singlet excited state (S1) to a ground state (S0) is called fluorescence and light emission by transition from a triplet excited state (T1) to the ground state (S0) is called phosphorescence. Fluorescence makes use of only 25% of a singlet excited state, which limits emission efficiency. Unlike fluorescence, phosphorescence makes use of both 75% of a triplet excited state and 25% of a singlet excited state, which can accomplish theoretically up to 100% internal quantum efficiency.

As light-emitting materials using a triplet excited state, there have been reported various phosphorescent materials using an iridium or platinum compound. In particular, as blue-emitting materials, there have been developed (4,6-F 2 ppy)₂Ir pic [Chihaya Adachi etc. Appl. Phys. Lett., 79, 2082-2084, 2001] and iridium compounds based on a fluorinated ppy ligand structure. However, with respect to the (4,6-F 2 ppy)₂Ir pic, light emission occurs in a sky blue range. In particular, a high shoulder peak increases y value in color purity.

In addition, blue phosphorescent materials lack suitable host materials, and thus, exhibit very low emission efficiency and lifetime characteristics, relative to red and green phosphorescent materials. Therefore, development of high-efficiency, long-lifetime, deep-blue phosphorescent materials would be advantageous.

### SUMMARY OF THE INVENTION

In view of problems of common blue-emitting materials, the present invention provides an iridium compound enabling high color purity and low power consumption.

The present invention also provides an organic EL device using an iridium compound set forth below, which is enhanced in brightness, driving voltage, and lifetime characteristics.

According to an aspect of the present invention, there is provided an iridium compound represented by the following formula 1: 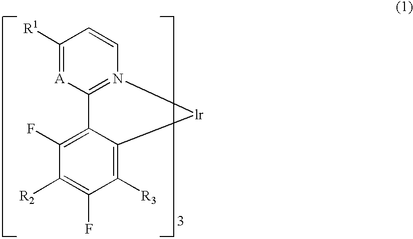
wherein A is CH or N; and
R₁, R₂, and R₃ are each independently a hydrogen atom, cyano group, hydroxy group, thiol group, nitro group, halogen atom, a substituted or unsubstituted C₁-C₃₀ alkyl group, a substituted or unsubstituted C₁-C₃₀ alkoxy group, a substituted or unsubstituted C₃-C₃₀ alkenyl group, a substituted or unsubstituted C₆-C₃₀ aryl group, a substituted or unsubstituted C₆-C₃₀ arylalkyl group, a substituted or unsubstituted C₆-C₃₀ aryloxy group, a substituted or unsubstituted C₂-C₃₀ heteroaryl group, a substituted or unsubstituted C₂-C₃₀ heteroarylalkyl group, a substituted or unsubstituted C₂-C₃₀ heteroaryloxy group, a substituted or unsubstituted C₅-C₃₀ cycloalkyl group, a substituted or unsubstituted C₃-C₃₀ heterocycloalkyl group, a substituted or unsubstituted C₁-C₃₀ alkylcarbonyl group, a substituted or unsubstituted C₇-C₃₀ arylcarbonyl group, a C₁-C₃₀ alkylthio group, —Si(R′)(R″)(R′″) where R′, R″ and R′″ are each independently a hydrogen atom or a C₁-C₃₀ alkyl group, or —N(R′)(R″) where R′ and R″ are each independently a hydrogen atom or a C₁-C₃₀ alkyl group.

When A of the formula 1 is CH, R₁ may be an electron donating group, R₂ and R₃ may be each an electron withdrawing group.

The electron donating group may be a methyl group, an isopropyl group, a phenyloxy group, a benzyloxy group, a dimethylamino group, a diphenylamino group, a pyrrolidine group, or a phenyl group, and the electron withdrawing group may be a fluoro group, a cyano group, a trifluoromethyl group, or a phenyl group with a trifluoromethyl moiety.

According to another aspect of the present invention, there is provided an organic EL device including an organic layer between a pair of electrodes, wherein the organic layer includes the above-described iridium compound.

The organic layer may be a light-emitting layer.

### BRIEF DESCRIPTION OF THE DRAWINGS

The above and other features and advantages of the present invention will become more apparent by describing in detail exemplary embodiments thereof with reference to the attached drawings in which:

FIG. 1 is a sectional view illustrating an organic EL device according to an embodiment of the present invention;

FIG. 2 is a photoluminescence (PL) spectrum of a compound represented by formula 2 according to the present invention;

FIG. 3 is a PL spectrum of a compound represented by formula 3 according to the present invention;

FIG. 4 is an electroluminescence (EL) spectrum of the compound represented by the formula 2 according to the present invention;

FIG. 5 is a graph illustrating a change in brightness with respect to voltage in an organic EL device manufactured in Example 1 according to the present invention;

FIG. 6 is a graph illustrating a change in current density with respect to voltage in the organic EL device manufactured in Example 1 according to the present invention; and

FIG. 7 is a graph illustrating a change in emission efficiency with respect to brightness in the organic EL device manufactured in Example 1 according to the present invention.

### DETAILED DESCRIPTION OF THE INVENTION

The present invention will now be described more fully with reference to the accompanying drawings, in which exemplary embodiments of the invention are shown.

The present invention provides an iridium compound of the following formula 1. 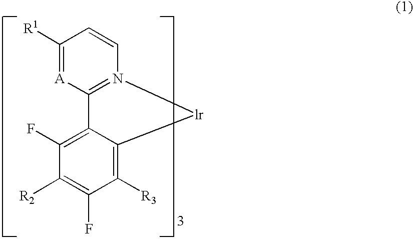
wherein A is CH or N; and
R₁, R₂, and R₃ are each independently, a hydrogen atom, cyano group, hydroxy group, thiol group, nitro group, halogen atom, a substituted or unsubstituted C₁-C₃₀ alkyl group, a substituted or unsubstituted C₁-C₃₀ alkoxy group, a substituted or unsubstituted C₂-C₃₀ alkenyl group, a substituted or unsubstituted C₆-C₃₀ aryl group, a substituted or unsubstituted C₆-C₃₀ arylalkyl group, a substituted or unsubstituted C₆-C₃₀ aryloxy group, a substituted or unsubstituted C₂-C₃₀ heteroaryl group, a substituted or unsubstituted C₂-C₃₀ heteroarylalkyl group, a substituted or unsubstituted C₂-C₃₀ heteroaryloxy group, a substituted or unsubstituted C₅-C₃₀ cycloalkyl group, a substituted or unsubstituted C₂-C₃₀ heterocycloalkyl group, a substituted or unsubstituted C₁-C₃₀ alkylcarbonyl group, a substituted or unsubstituted C₇-C₃₀ arylcarbonyl group, a C₁-C₃₀ alkylthio group, —Si(R′)(R″)(R′″) where R′, R″ and R′″ are each independently a hydrogen atom or a C₁-C₃₀ alkyl group, or —N(R′)(R″) where R′ and R″ are each independently a hydrogen atom or a C₁-C₂₀ alkyl group.

In formula 1, when A is CH, it is preferable that R₁ is an electron donating group, and that R₂ and R₃ are each an electron withdrawing group. Therefore, the iridium compound according to the present invention can increase an energy gap between highest occupied molecular orbital (HOMO) and lowest occupied molecular orbital (LUMO) in a triplet state, relative to phenylpyridine. Such an increase in the HOMO-LUMO energy gap induces transition to blue-emitting wavelength, resulting in deep blue emission.

The electron donating group may be a methyl group, an isopropyl group, a phenyloxy group, a benzyloxy group, a dimethylamino group, a diphenylamino group, a pyrrolidine group, or a phenyl group, and the electron withdrawing group may be a fluoro group, a cyano group, a trifluoromethyl group, or a phenyl group with a trifluoromethyl moiety.

In one embodiment of formula 1, A is CH or N, R₁ is a hydrogen atom, a methyl group, a pyrrolidyl group, a dimethylamino group, or a phenyl group, R₂ is a cyano group, CF₃, C₆F₅, or a nitro group, and R₃ is a hydrogen atom or a cyano group. These compounds are summarized in Table 1 below.

TABLE 1

| Compound No. | A | R1 | R2 | R3 |
|---|---|---|---|---|
| 1 | CH | H | CN | CN |
| 2 | CH | H | CF3 | H |
| 3 | CH | H | CF3 | CN |
| 4 | CH | H | C6F5 | H |
| 5 | CH | H | C6F5 | CN |
| 6 | CH | H | NO2 | H |
| 7 | CH | H | NO2 | CN |
| 8 | CH | CH3 | CN | H |
| 9 | CH | CH3 | CN | CN |
| 10 | CH | CH3 | CF3 | H |
| 11 | CH | CH3 | CF3 | CN |
| 12 | CH | CH3 | C6F5 | H |
| 13 | CH | CH3 | C6F5 | CN |
| 14 | CH | CH3 | NO2 | H |
| 15 | CH | CH3 | NO2 | CN |
| 16 | CH | pyrrolidine | CN | H |
| 17 | CH | pyrrolidine | CN | CN |
| 18 | CH | pyrrolidine | CF3 | H |
| 19 | CH | pyrrolidine | CF3 | CN |
| 20 | CH | pyrrolidine | C6F5 | H |
| 21 | CH | pyrrolidine | C6F5 | CN |
| 22 | CH | pyrrolidine | NO2 | H |
| 23 | CH | pyrrolidine | NO2 | CN |
| 24 | CH | (CH3)2N | CN | H |
| 25 | CH | (CH3)2N | CN | CN |
| 26 | CH | (CH3)2N | CF3 | H |
| 27 | CH | (CH3)2N | CF3 | CN |
| 28 | CH | (CH3)2N | C6F5 | H |
| 29 | CH | (CH3)2N | C6F5 | CN |
| 30 | CH | (CH3)2N | NO2 | H |
| 31 | CH | (CH3)2N | NO2 | CN |
| 32 | CH | C6H5 | CN | H |
| 33 | CH | C6H5 | CN | CN |
| 34 | CH | C6H5 | CF3 | H |
| 35 | CH | C6H5 | CF3 | CN |
| 36 | CH | C6H5 | C6F5 | H |
| 37 | CH | C6H5 | C6F5 | CN |
| 38 | CH | C6H5 | NO2 | H |
| 39 | CH | C6H5 | NO2 | CN |
| 40 | N | H | CN | H |
| 41 | N | H | CN | CN |
| 42 | N | H | CF3 | H |
| 43 | N | H | CF3 | CN |
| 44 | N | H | C6F5 | H |
| 45 | N | H | C6F5 | CN |
| 46 | N | H | NO2 | H |
| 47 | N | H | NO2 | CN |
| 48 | N | CH3 | CN | H |
| 49 | N | CH3 | CN | CN |
| 50 | N | CH3 | CF3 | H |
| 51 | N | CH3 | CF3 | CN |
| 52 | N | CH3 | C6F5 | H |
| 53 | N | CH3 | C6F5 | CN |
| 54 | N | CH3 | NO2 | H |
| 55 | N | CH3 | NO2 | CN |
| 56 | N | pyrrolidine | CN | H |
| 57 | N | pyrrolidine | CN | CN |
| 58 | N | pyrrolidine | CF3 | H |
| 59 | N | pyrrolidine | CF3 | CN |
| 60 | N | pyrrolidine | C6F5 | H |
| 61 | N | pyrrolidine | C6F5 | CN |
| 62 | N | pyrrolidine | NO2 | H |
| 63 | N | pyrrolidine | NO2 | CN |
| 64 | N | (CH3)2N | CN | H |
| 65 | N | (CH3)2N | CN | CN |
| 66 | N | (CH3)2N | CF3 | H |
| 67 | N | (CH3)2N | CF3 | CN |
| 68 | N | (CH3)2N | C6F5 | H |
| 69 | N | (CH3)2N | C6F5 | CN |
| 70 | N | (CH3)2N | NO2 | H |
| 71 | N | (CH3)2N | NO2 | CN |
| 72 | N | C6H5 | CN | H |
| 73 | N | C6H5 | CN | CN |
| 74 | N | C6H5 | CF3 | H |
| 75 | N | C6H5 | CF3 | CN |
| 76 | N | C6H5 | C6F5 | H |
| 77 | N | C6H5 | C6F5 | CN |
| 78 | N | C6H5 | NO2 | H |
| 79 | N | C6H5 | NO2 | CN |

Preferably, the iridium compound of formula 1 according to the present invention is a compound of the following formula 2 or 3:

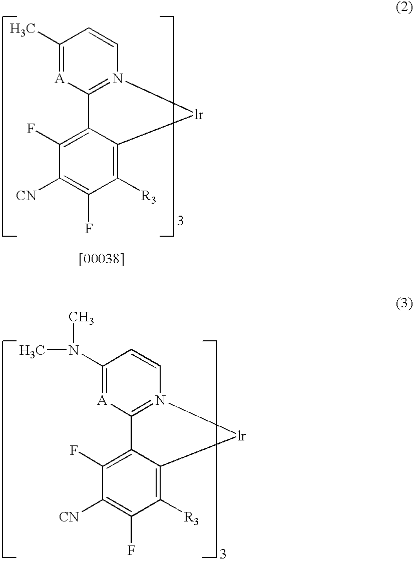

In particular, the compounds of formulae 2 and 3 are novel deep-blue phosphorescent materials and are useful as dopants.

The iridium compound of the formula 1 can be synthesized using a method disclosed in M. E. Thompson et al. Inorg. Chem. 2001, 40, 1704-1711, the disclosure of which is incorporated herein by reference.

A synthetic method for an iridium compound according to the present invention will now be described with reference to the following scheme 1.

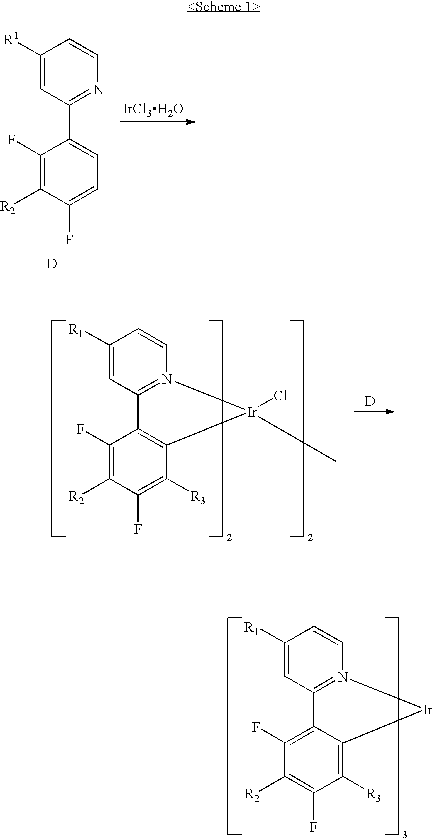

First, a compound D is prepared as in scheme 2. Then, compound D reacts with iridium chloride to produce a dimer. The dimer production procedure can be diversely selected according to the types of R₁, R₂, and R₃, but may be performed at 100 to 150° C.

The dimer thus produced reacts with the compound D in the presence of a compound such as silver trifluoroacetate (CF₃COOAg) to produce the iridium compound of the formula 1. The compound such as silver trifluoroacetate is used in an amount of 1.1 to 1.5 moles, based on 1 mole of the dimer. The reaction temperature may be in the range from 160 to 250° C., preferably from 180 to 200° C.

Examples of the unsubstituted C₁-C₃₀ alkyl group as used herein include methyl, ethyl, propyl, isobutyl, sec-butyl, pentyl, iso-amyl, and hexyl. One or more hydrogen atoms on the alkyl group may be substituted by a halogen atom, a hydroxy group, a nitro group, a cyano group, an amino group, an amidino group, hydrazine, hydrazone, a carboxyl group or its salt, a sulfonic acid group or its salt, a phosphoric acid group or its salt, a C₁-C₃₀ alkyl group, a C₁-C₃₀ alkenyl group, a C₁-C₃₀ alkynyl group, an C₆-C₃₀ aryl group a C₇-C₃₀ arylalkyl group, a C₂-C₂₀ heteroaryl group, or a C₃-C₃₀ heteroarylalkyl group.

Examples of the unsubstituted alkoxy group of C₁-C₃₀ as used herein include methoxy, ethoxy, phenyloxy, cyclohexyloxy, naphthyloxy, isopropyloxy, and diphenyloxy. One or more hydrogen atoms on the alkoxy group may be substituted by the same substituents as those mentioned in the alkyl group.

The unsubstituted aryl group as used herein, which is used alone or in combination, refers to a carbocyclic aromatic system of 6-30 carbon atoms containing one or more rings. The rings may be attached to each other as a pendant group or may be fused. Examples of the aryl group include phenyl, naphthyl, and tetrahydronaphthyl. One or more hydrogen atoms on the aryl group may be substituted by the same substituents as those mentioned in the alkyl group.

Examples of the unsubstituted aryloxy group as used herein include phenyloxy, naphthyloxy, and diphenyloxy. One or more hydrogen atoms on the aryloxy group may be substituted by the same substituents as those mentioned in the alkyl group.

The unsubstituted arylalkyl group as used herein refers to a lower alkyl, for example, methyl, ethyl, or propyl appended to the aryl as defined in the above. Examples of the arylalkyl group include benzyl and phenylethyl. One or more hydrogen atoms on the arylalkyl group may be substituted by the same substituents as those mentioned in the alkyl group.

The unsubstituted heteroaryl group as used herein refers to a monovalent aromatic compound of 6-70 carbon atoms containing one, two or three hetero atoms selected from N, O, P and S. Examples of the heteroaryl group include thienyl, pyridyl, and furyl. One or more hydrogen atoms on the heteroaryl group may be substituted by the same substituents as those mentioned in the alkyl group.

The unsubstituted heteroaryloxy group as used herein refers to oxygen appended to the heteroaryl as defined in the above. Examples of the heteroaryloxy group include benzyloxy and phenylethyloxy. One or more hydrogen atoms on the heteroaryloxy group may be substituted by the same substituents as those mentioned in the alkyl group.

The unsubstituted arylalkyloxy group as used herein may be a benzyloxy group. One or more hydrogen atoms on the arylalkyloxy group may be substituted by the same substituents as those mentioned in the alkyl group.

The unsubstituted heteroarylalkyl group as used herein refers to an alkyl group appended to the heteroaryl as defined in the above. An example of the heteroarylalkyl group may be a compound represented by the following structural formula. One or more hydrogen atoms on the heteroarylalkyl group may be substituted by the same substituents as those mentioned in the alkyl group.

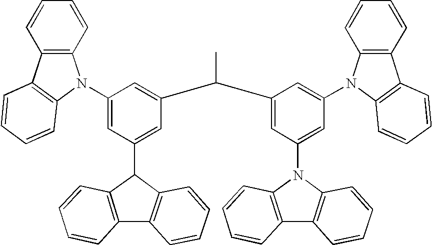

Examples of the unsubstituted cycloalkyl group as used herein include a cyclohexyl group and a cyclopentyl group. One or more hydrogen atoms on the cycloalkyl group may be substituted by the same substituents as those mentioned in the alkyl group.

Examples of the unsubstituted C₁-C₃₀ alkylcarbonyl group as used herein include acetyl, ethylcarbonyl, isopropylcarbonyl, phenylcarbonyl, naphthylcarbonyl, diphenylcarbonyl, and cyclohexylcarbonyl. One or more hydrogen atoms on the alkylcarbonyl group may be substituted by the same substituents as those mentioned in the alkyl group.

Examples of the unsubstituted C₇-C₃₀ arylcarbonyl as used herein include phenylcarbonyl, naphthylcarbonyl, and diphenylcarbonyl. One or more hydrogen atoms on the arylcarbonyl group may be substituted by the same substituents as those mentioned in the alkyl group.

A method of manufacturing an organic EL device according to the present invention is also described.

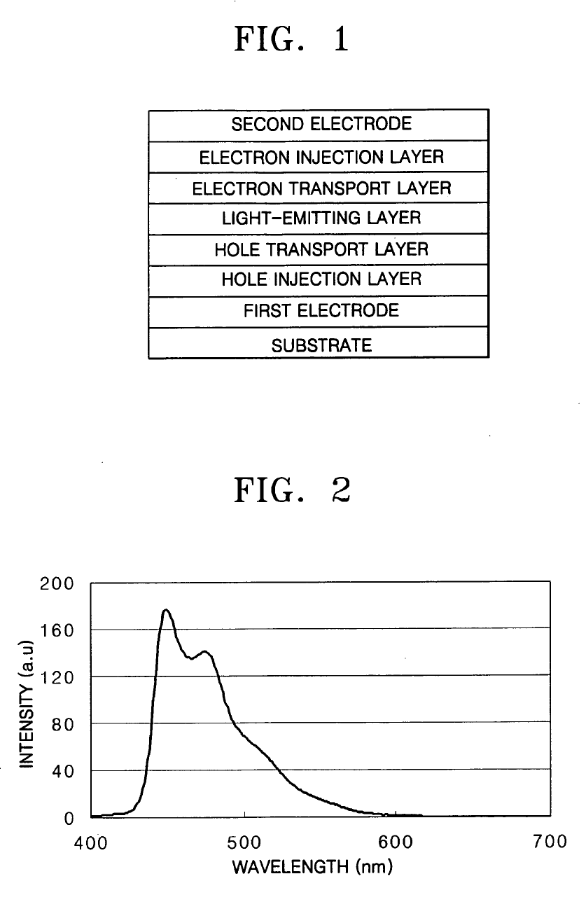

FIG. 1 is a sectional view illustrating an organic EL device according to the present invention and a conventional technique. First, an anode material is coated on a substrate to form an anode used as a first electrode. The substrate may be a substrate commonly used for organic EL devices. Preferably, the substrate is a glass substrate or a transparent plastic substrate which is high in transparency, surface smoothness, handling property, and water resistance. The anode material may be a material which is high in transparency and conductivity, for example indium tin oxide (ITO), tin oxide (SnO₂), or zinc oxide (ZnO).

A hole injection layer is selectively formed on the anode by vacuum deposition or spin coating of a hole injection layer material. The hole injection layer material is not particularly limited but may be CuPc or a Starburst amine compound such as TCTA, m-MTDATA, and IDE406 (Idemitsu) as represented by the following structural formulae:

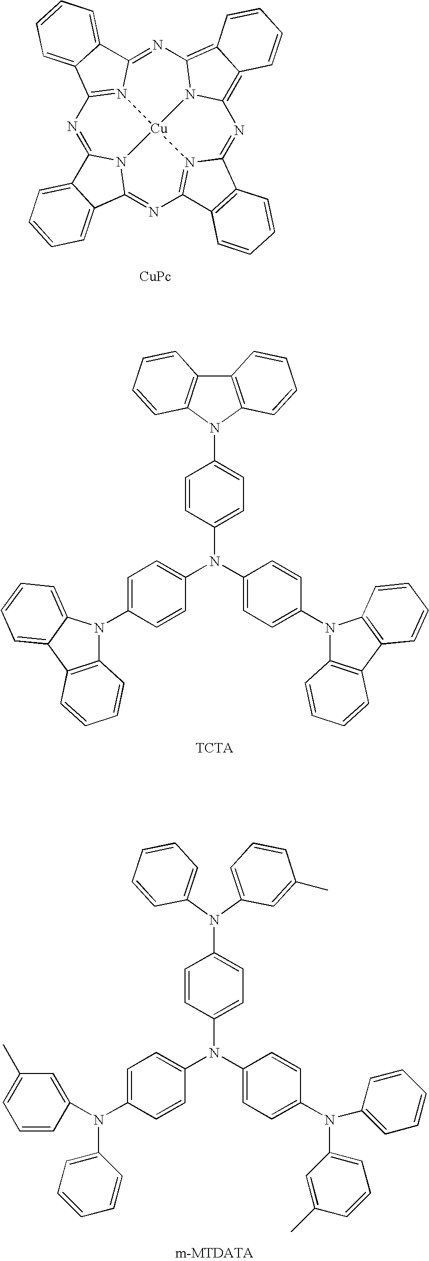

Next, a hole transport layer is formed by vacuum deposition or spin coating of a hole transport layer material.

The hole transport layer material is not particularly limited but may be N,N′-bis(3-methylphenyl)-N,N′-diphenyl-[1,1-biphenyl]-4,4′-diamine (“TPD”), N,N′-di(naphthylene-1-yl)-N,N′-diphenylbenzidine (“α-NPD”), etc.

Next, a light-emitting layer is formed on the hole transport layer. The light-emitting layer may be formed using only a metal compound as represented by the formula 1, in particular, an iridium compound as represented by the formula 2 or 3. Alternatively, the light-emitting layer may be formed by vacuum thermal co-deposition of the above metal compounds as a dopant and a host such as CBP, TCB, TCTA, SDI-BH-18, SDI-BH-19, SDI-BH-22, SDI-BH-23, and dmCBP as set forth in the formulae below. Here, the doping concentration of the dopant is not particularly limited but the dopant may be contained in the light-emitting layer in an amount of 1 to 20 parts by weight, based on the total weight (100 parts by weight) of a light-emitting layer forming material (i.e., the total weight of the host and the dopant). If the content of the dopant is less than 1 part by weight, an addition effect may be insufficient. On the other hand, if it exceeds 20 parts by weight, concentration extinction may occur.

Next, an electron transport layer is formed on the light-emitting layer by vacuum deposition or spin coating of an electron transport layer material. The electron transport layer material may be Alq3. A hole blocking layer is selectively formed between the light-emitting layer and the electron transport layer.

Then, an electron injection layer may be formed on the electron transport layer. An electron injection layer material is not particularly limited but may be LiF, NaCl, CsF, etc.

Finally, a cathode used as a second electrode is formed on the electron injection layer by vacuum deposition of a cathode metal to complete an organic EL device. The cathode metal may be lithium (Li), magnesium (Mg), aluminum (Al), aluminum-lithium (Al—Li), calcium (Ca), magnesium-indium (Mg—In), magnesium-silver (Mg—Ag), or the like.

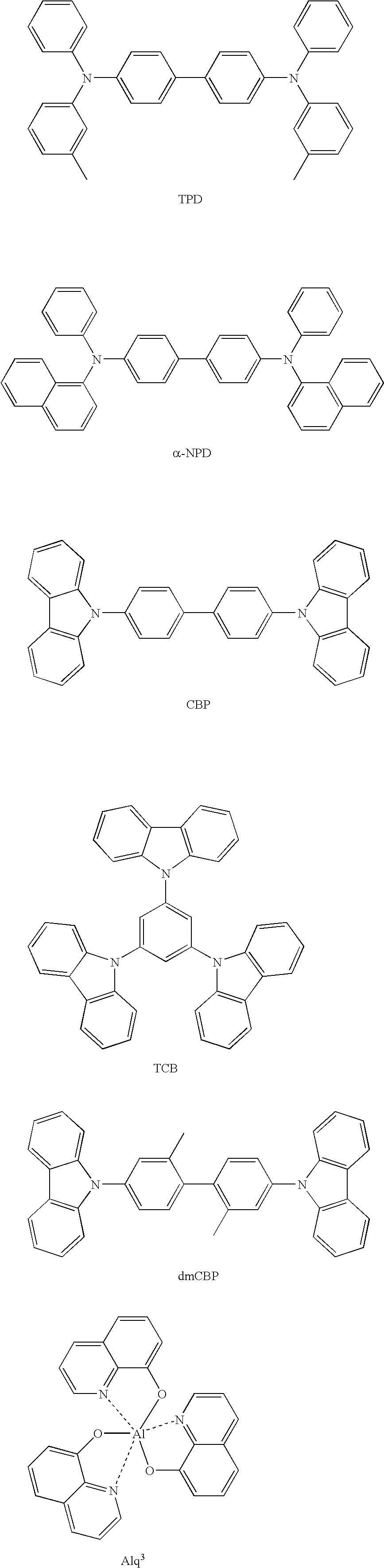

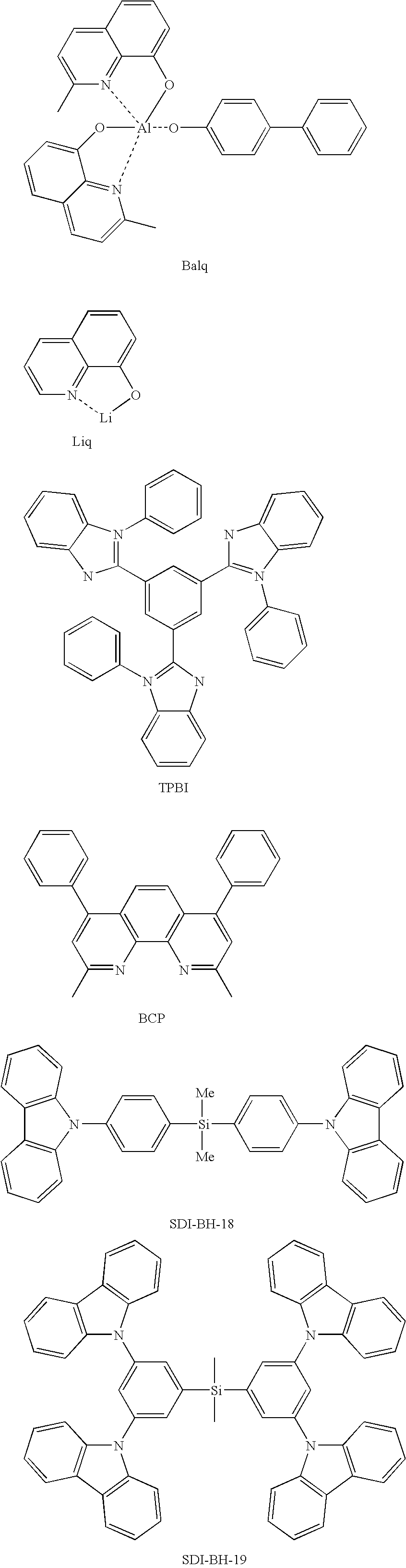

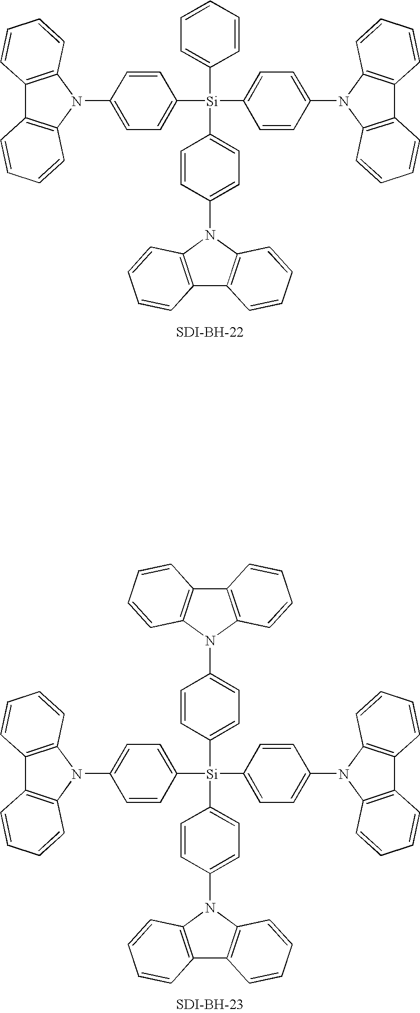

An organic EL device of the present invention may include, as needed, one or two interlayers among an anode, a hole injection layer, a hole transport layer, a light-emitting layer, an electron transport layer, an electron injection layer, and a cathode.

Hereinafter, the present invention will be described more specifically by Examples. However, the following Examples are provided only for illustrations and thus the present invention is not limited to or by them.

### SYNTHESIS EXAMPLE 1

### Compound Represented by Formula 2

A compound represented by formula 2 was synthesized according to the following scheme 2:

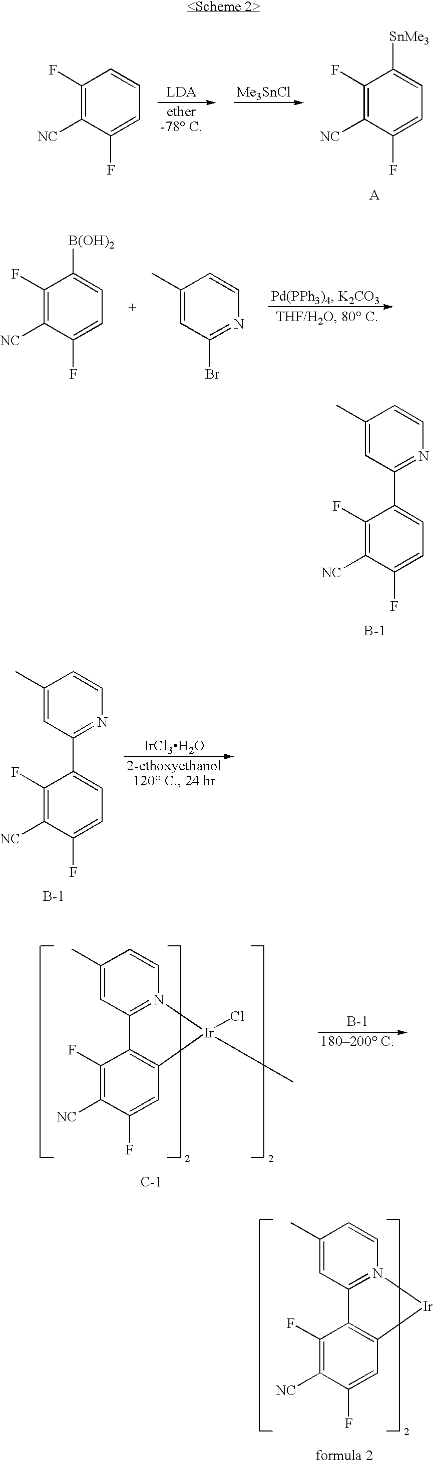

Synthesis of Intermediate (A)

6.0 mL (12.0 mmol) of lithium diisopropylamide (LDA) was dropwise added to a solution of 1.4 g (10.0 mmol) of difluorobenzonitrile in 50 mL of diethyl ether at −78° C. and stirred for one hour. Then, 12.5 mL (12.5 mmol) of a 1M trimethyltin chloride solution was added to the reaction mixture and stirred at room temperature for one hour.

After the reaction was terminated, 20 mL of a 5% sodium hydroxide aqueous solution was added to the reaction solution and the aqueous layer was neutralized with a 3N HCl solution. The resultant solution was separated into an aqueous layer and an organic layer to isolate the organic layer. The aqueous layer was three times extracted with 20 mL of ethyl acetate, and collected organic layers were dried over magnesium sulfate then evaporated to dryness. The resultant residue was dried under vacuum to give 2.0 g (yield: 66%) of a white solid (A).

Synthesis of Intermediate (B-1)

1.08 mg (3.6 mmol) of the intermediate (A) and 0.4 mL (3.0 mmol) of 2-bromo-4-methylpyridine were dissolved in 18 mL of DMF. Then, 200 mg (0.18 mmol) of palladium tetrakistriphenylphosphine and 2.48 g (17.9 mmol) of K₂CO₃ were added and the resultant solution was stirred at 120° C. for one hour.

After the reaction was terminated, the reaction solution was extracted three times with ethyl ether (10 mL for each). The organic layer was collected and dried over magnesium sulfate then evaporated to dryness. The resultant residue was purified by silica gel column chromatography to give 570 mg (yield: 88%) of compound (B-1), which was identified by ¹H NMR.

¹H NMR (CDCl₃, 400 MHz) δ (ppm) 8.56 (d, J=4.92 Hz, 1H), 7.72 (m, 1H), 7.55 (s, 1H), 7.12-7.06 (m, 2H), 2.42 (s, 3H)

Synthesis of Intermediate (C-1)

2.0 g (8.09 mmol) of the intermediate (B-1) was dissolved in 45 mL of 2-ethoxyethanol. Then, 1.1 g of iridium (III) chloride hydrate and 15 mL of distilled water were added thereto and stirred at 120° C. for 24 hours. The reaction solution was cooled to room temperature. The resultant precipitate was isolated and was washed with methanol and dried under vacuum to give 1.6 g of an intermediate (C-1).

Synthesis of the Compound of the Formula 2

1.0 g (0.69 mmol) of the intermediate (C-1), 343 mg(1.4 mmol) of the intermediate (B-1), and 0.69 mmol of silver trifluoroacetate were mixed at 180-200° C. for two hours.

After the reaction was terminated, the reaction solution was diluted with dichloromethane and washed with distilled water. The organic layer was isolated and was dried over magnesium sulfate then evaporated to dryness. The resultant residue was purified by silica gel column chromatography to give 1.0 mg (yield: 55%) of a compound of the formula 2, which was identified by ¹H NMR.

¹H NMR (CDCl₃, 400 MHz) δ (ppm) 8.19 (s, 1H), 8.11 (s, 2H), 7.71 (d, 1H), 7.64 (d, 1H), 7.24 (s, 1H), 6.95 (d, 1H), 6.82 (m, 2H), 6.44 (d, 1H), 6.05 (d, 1H), 5.87 (d, 1H), 2.59 (s, 9H)

### SYNTHESIS EXAMPLE 2

### Compound of Formula 3

A compound of formula 3 was synthesized according to the following scheme 3:

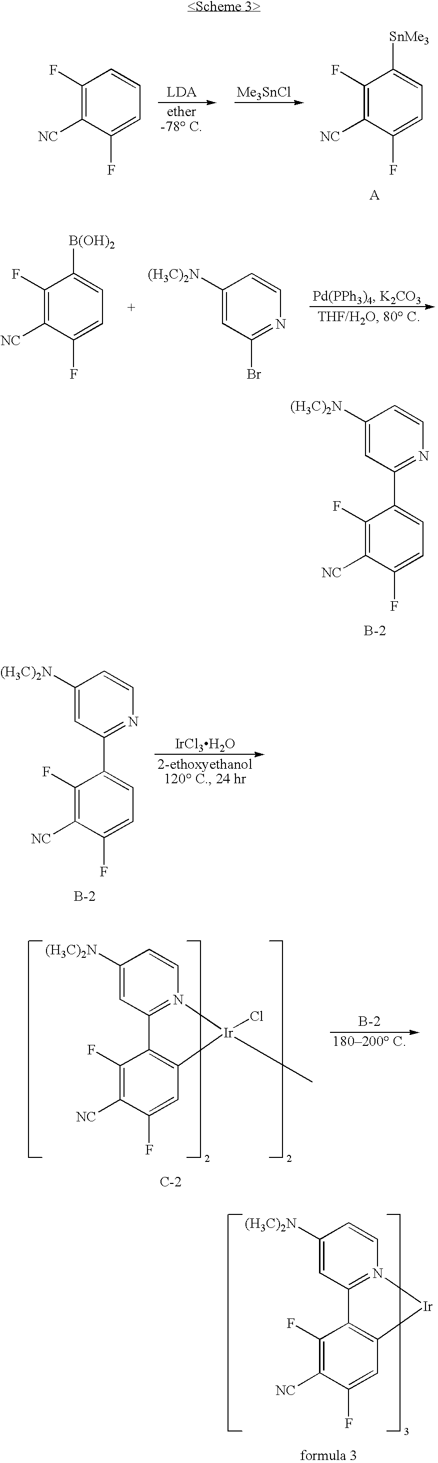

Synthesis of Intermediate (B-2)

1.08 mg (3.6 mmol) of the intermediate (A) and 366 mg (3.0 mmol) of 2-bromo-4-dimethylaminopyridine were dissolved in 18 mL of DMF. Then, 200 mg (0.18 mmol) of palladium tetrakistriphenylphosphine and 2.48 g (17.9 mmol) of K₂CO₃ were added and the resultant solution stirred at 120° C. for one hour.

The reaction solution was extracted three times with ethyl ether (10 mL for each). The organic layer was collected and was dried over magnesium sulfate to evaporate a solvent. The resultant residue was purified by silica gel column chromatography to give 715 mg (yield: 92%) of a compound (B-2), which was identified by ¹H NMR.

¹H NMR (CDCl₃, 400 MHz) δ (ppm) 8.31-8.25 (m, 2H), 7.16 (m, 1H), 6.98 (s, 1H), 6.54 (m, 1H), 3.07 (s, 6H)

Synthesis of Intermediate (C-2)

2.0 g (7.71 mmol) of the intermediate (B-2) was dissolved in 45 mL of 2-ethoxyethanol. 1.14 g of iridium (III) chloride hydrate and 15 mL of distilled water were added thereto and stirred at 120° C. for 24 hours.

The reaction mixture was cooled to room temperature. The resultant precipitate was washed with methanol and dried under vacuum to give 1.50 g of an intermediate (C-2).

Synthesis of Compound of the Formula 3

615 mg (0.41 mmol) of the intermediate (C-2), 235 mg(0.91 mmol) of the intermediate (B-2), and 0.41 mmol of silver trifluoroacetate were mixed at 180-200° C. for two hours.

After the reaction was terminated, the dichloromethane was added to the reaction solution which was then washed with distilled water. The organic layer was separated and was dried over magnesium sulfate and evaporated to dryness. The resultant residue was purified by recrystallization to give 436 mg (yield: 55%) of a compound of the formula 3, which was identified by ¹H NMR.

¹H NMR (CDCl₃, 400 MHz) δ (ppm) 7.51 (m, 1H), 7.43-7.42 (m, 2H), 7.36-7.32 (m, 2H), 7.06 (d, 1H), 6.47 (d, 1H), 6.27 (m, 1H), 6.21-6.18 (m, 3H), 6.04 (d, 1H), 3.11 (s, 18H)

The compound of the formula 2 synthesized in Synthesis Example 1 was dissolved in CH₂Cl₂ (0.02 mM) and exposed to 370 nm UV to measure a photoluminescence (PL) spectrum. The result is shown in FIG. 2.

As shown in FIG. 2, a maximum PL peak was observed at 449 nm. At this time, the color purity of the PL spectrum with NTSC chromaticity coordinates was as follows: ClE(x,y): (0.14, 0.15).

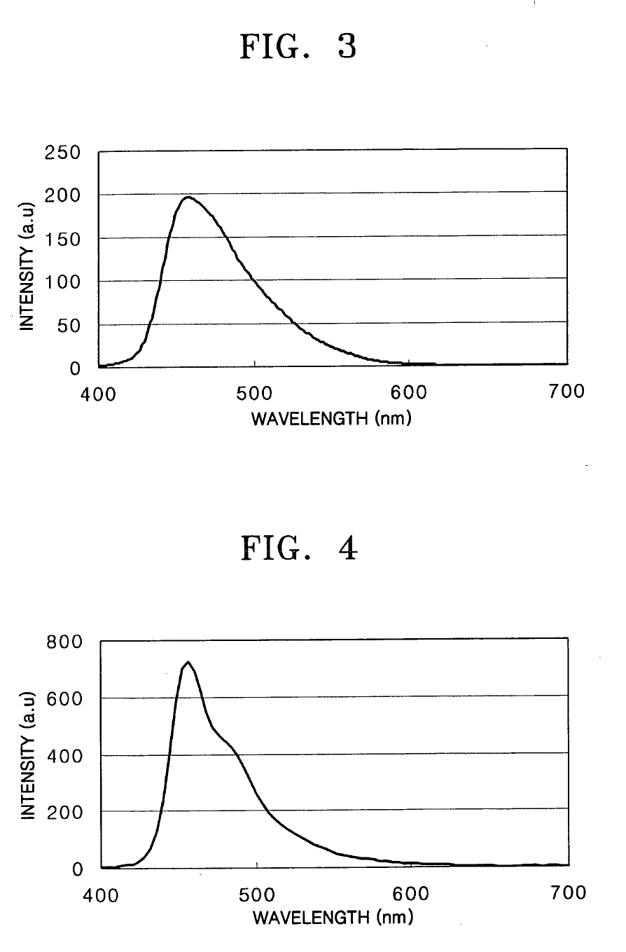

The compound of the formula 3 synthesized in Synthesis Example 2 was dissolved in CH₂Cl₂ (0.02 mM) and exposed to 370 nm UV to measure a PL spectrum. The result is shown in FIG. 3.

As shown in FIG. 3, a maximum PL peak was observed at 457 nm. At this time, the color purity of the PL spectrum with NTSC chromaticity coordinates was as follows: ClE(x,y): (0.14, 0.16).

### EXAMPLE 1

### Fabrication of Organic EL Device

A Corning 15 Ω/cm² (1,200 Å) ITO glass substrate was cut into pieces of 50 mm×50 mm×0.7 mm in size, followed by ultrasonic cleaning in isopropyl alcohol and deionized water (5 minutes for each) and then UV/ozone cleaning (30 minutes), to be used as an anode.

A hole injection layer was formed to a thickness of 600 Å on the substrate by vacuum deposition of IDE406 (Idemitsu). Then, a hole transport layer was formed to a thickness of 300 Å on the hole injection layer by vacuum deposition of IDE320 (Idemitsu). After forming the hole transport layer, a light-emitting layer was formed to a thickness of 300 Å on the hole transport layer by vacuum co-deposition of 90 parts by weight of SDI-BH-23 as a host and 10 parts by weight of a compound of the formula 2 as a dopant.

Next, a hole blocking layer was formed to a thickness of 50 Å on the light-emitting layer by vacuum deposition of Balq. Then, an electron transport layer was formed to a thickness of 200 Å on the hole blocking layer by vacuum deposition of Alq₃. An LiF/Al electrode was formed on the electron transport layer by sequential vacuum deposition of LiF (10 Å, electron injection layer) and Al (1,000 Å, cathode) to complete an organic EL device as shown in FIG. 1.

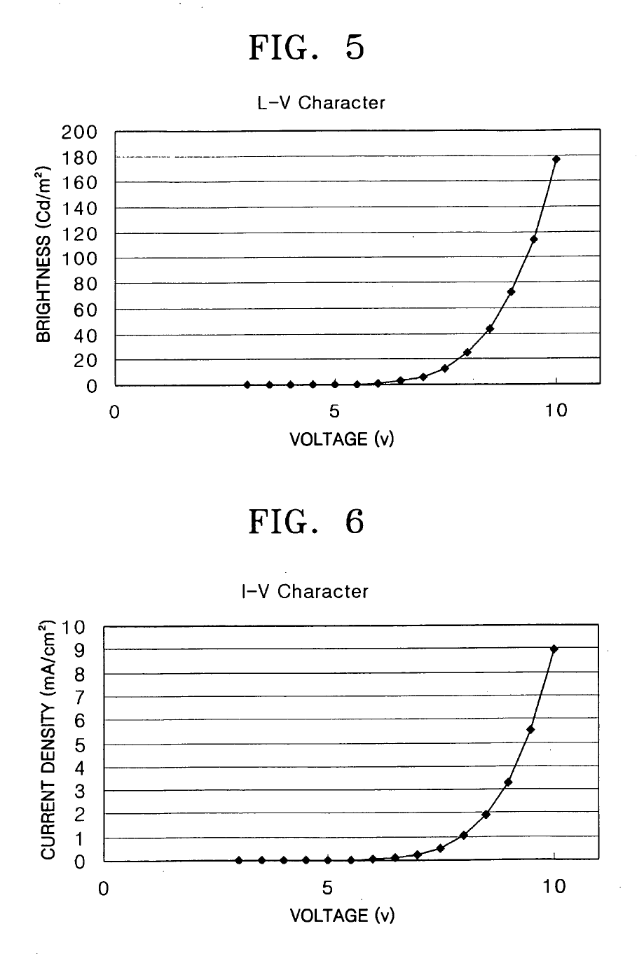

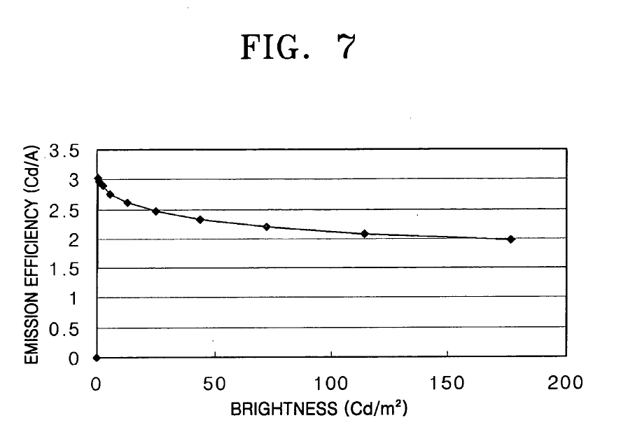

The organic EL device of Example 1 exhibited a brightness of 114 cd/m² at DC voltage of 9.5V (current density: 5.5 mA/cm²), emission efficiency of 2.1 cd/A, and chromaticity coordinates (0.15, 0.15), resulting in blue emission with good color purity (see FIGS. 4 through 7).

An iridium compound represented by the formula 1 according to the present invention is particularly useful as a blue phosphorescent material, and is excellent in color purity and emission efficiency characteristics. Use of such an iridium compound as a dopant, together with a blue phosphorescent host, in formation of a light-emitting layer, can produce a blue-emitting organic EL device with good chromaticity characteristics.

Employment of an organic layer made of the above-described iridium compound, in particular a light-emitting layer enables fabrication of a good blue-emitting organic EL device with high brightness, high emission efficiency, a low driving voltage, high color purity, and extended lifetime characteristics.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. An iridium compound of the following formula 1: 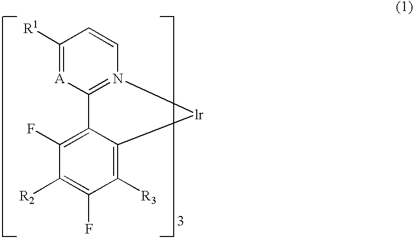
wherein A is CH or N; and
R₁, R₂, and R₃ are each independently a hydrogen atom, cyano group, hydroxy group, thiol group, nitro group, halogen atom, a substituted or unsubstituted C₁-C₃₀ alkyl group, a substituted or unsubstituted C₁-C₃₀ alkoxy group, a substituted or unsubstituted C₂-C₃₀ alkenyl group, a substituted or unsubstituted C₆-C₃₀ aryl group, a substituted or unsubstituted C₆-C₃₀ arylalkyl group, a substituted or unsubstituted C₆-C₃₀ aryloxy group, a substituted or unsubstituted C₂-C₃₀ heteroaryl group, a substituted or unsubstituted C₂-C₃₀ heteroarylalkyl group, a substituted or unsubstituted C₂-C₃₀ heteroaryloxy group, a substituted or unsubstituted C₅-C₃₀ cycloalkyl group, a substituted or unsubstituted C₂-C₃₀ heterocycloalkyl group, a substituted or unsubstituted C₁-C₃₀ alkylcarbonyl group, a substituted or unsubstituted C₇-C₃₀ arylcarbonyl group, a C₁-C₃₀ alkylthio group, —Si(R′)(R″)(R′″) where R′, R″ and R′″ are each independently a hydrogen atom or a C₁-C₃₀ alkyl group, or —N(R′)(R″) where R′ and R″ are each independently a hydrogen atom or a C₁-C₃₀alkyl group.

2. The iridium compound of claim 1, wherein when A of the formula 1 is CH, R₁ is an electron donating group and R₂ and R₃ are each an electron withdrawing group.

3. The iridium compound of claim 2, wherein the electron donating group is a methyl group, an isopropyl group, a phenyloxy group, a benzyloxy group, a dimethylamino group, a diphenylamino group, a pyrrolidine group, or a phenyl group.

4. The iridium compound of claim 2, wherein the electron withdrawing group is a fluoro group, a cyano group, a trifluoromethyl group, or a phenyl group with a trifluoromethyl moiety.

5. The iridium compound of claim 1, wherein in the formula 1, A is CH or N; R₁ is a hydrogen atom, a methyl group, a pyrrolidyl group, a dimethylamino group, or a phenyl group; R₂ is a cyano group, CF₃, C₆F₅, or a nitro group; and R₃ is a hydrogen atom or a cyano group.

6. The iridium compound of claim 1, which is a compound of the following formula 2:

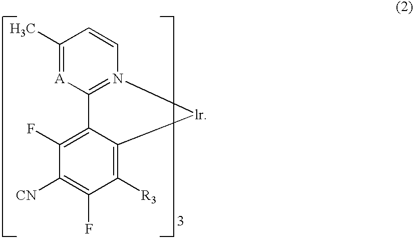

7. The iridium compound of claim 1, which is a compound of the following formula 3:

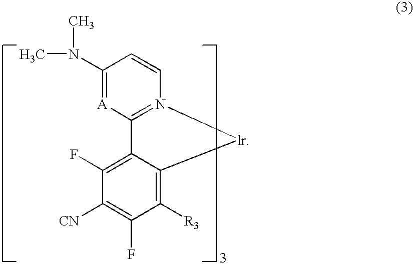

8. An organic EL device comprising an organic layer between a pair of electrodes, wherein the organic layer comprises an iridium compound of the following formula 1: 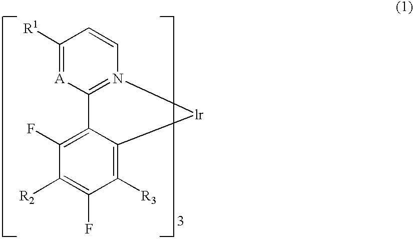
wherein A is CH or N; and
R₁, R₂, and R₃ are each independently a hydrogen atom, cyano group, hydroxy group, thiol group, nitro group, halogen atom, a substituted or unsubstituted C₁-C₃₀ alkyl group, a substituted or unsubstituted C₁-C₃₀ alkoxy group, a substituted or unsubstituted C₂-C₃₀ alkenyl group, a substituted or unsubstituted C₆-C₃₀ aryl group, a substituted or unsubstituted C₆-C₃₀ arylalkyl group, a substituted or unsubstituted C₆-C₃₀ aryloxy group, a substituted or unsubstituted C₂-C₃₀ heteroaryl group, a substituted or unsubstituted C₂-C₃₀ heteroarylalkyl group, a substituted or unsubstituted C₂-C₃₀ heteroaryloxy group, a substituted or unsubstituted C₅-C₃₀ cycloalkyl group, a substituted or unsubstituted C₂-C₃₀ heterocycloalkyl group, a substituted or unsubstituted C₁-C₃₀ alkylcarbonyl group, a substituted or unsubstituted C₇-C₃₀ arylcarbonyl group, an C₁-C₃₀ alkylthio group, —Si(R′)(R″)(R′″) where R′ and R″ are each independently a hydrogen atom or a C₁-C₃₀ alkyl group, or —N(R′)(R″) where R′ and R″ are each independently a hydrogen atom or a C₁-C₃₀ alkyl group.

9. The organic EL device of claim 8, wherein the organic layer is a light-emitting layer.

10. The organic EL device of claim 8, wherein the light-emitting layer comprises the iridium compound of 1 to 20 parts by weight, based on 100 parts by weight of a light-emitting layer forming material.

11. The organic EL device of claim 8, wherein when A of the formula 1 is CH, R₁ is an electron donating group and R₂ and R₃ are each an electron withdrawing group.

12. The organic EL device of claim 11, wherein the electron donating group is a methyl group, an isopropyl group, a phenyloxy group, a benzyloxy group, a dimethylamino group, a diphenylamino group, a pyrrolidine group, or a phenyl group.

13. The organic EL device of claim 11, wherein the electron withdrawing group is a fluoro group, a cyano group, a trifluoromethyl group, or a phenyl group substituted with a trifluoromethyl moiety.

14. The organic EL device of claim 8, wherein in the formula 1, A is CH or N; R₁ is a hydrogen atom, a methyl group, a pyrrolidyl group, a dimethylamino group, or a phenyl group; R₂ is a cyano group, CF₃, C₆F₅, or a nitro group; and R₃ is a hydrogen atom or a cyano group.

15. The organic EL device of claim 8, wherein the iridium compound is a compound of the following formula 2:

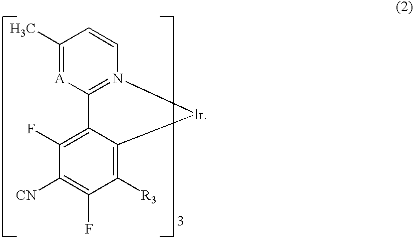

16. The organic EL device of claim 8, wherein the iridium compound is a compound of the following formula 3: [chemical structure]
